(19) United States
(12) Patent Application Publication
(10) Pub. No.: US 2026/0194472 A1
(43) Pub. Date: Jul. 9, 2026

(54) SEMICONDUCTOR DEVICES WITH PROTECTIVE LAYERS THAT FACILITATE DETECTION OF MICROCRACKS

(71) Applicant: Sandisk Technologies, Inc., Milpitas, CA (US)

(72) Inventors: Muhamad Ridhwan Hafiz bin Rosdi, Nibong Tebal (MY); Muhammad Faizul Mohd Yunus, Georgetown (MY); Cindirella Quinit Noromor, Bayan Lepas (MY); Hubert Tolentino Helera, Alaminos (PH)

(21) Appl. No.: 19/014,102

(22) Filed: Jan. 8, 2025

(51) Int. Cl. G01N 21/95; G01N 21/88

(52) U.S. Cl. CPC G01N 21/9505; G01N 21/8806

(57) ABSTRACT

A semiconductor device includes a protective layer with fluorescent indicators that facilitate detection of microcracks in the protective layer and, potentially, other portions of the semiconductor device. The protective layer, which is located over an active layer of the semiconductor device (e.g., its circuits and the metal layer over the circuits), may comprise polyimide with fluorescent indicators dispersed throughout the polyimide. The fluorescent indicators may comprise microcapsules with polymeric shells that rupture when a microcapsule lies in the path of and is intersected by a microcrack. As a polymeric shell ruptures, a fluorescent core of the microcapsule is exposed and may flow into the microcrack. The exposed fluorescent core may be excited by an appropriate wavelength or bandwidth of electromagnetic radiation and, thus, any microcracks in or adjacent to the protective layer may be visualized by radiographic imaging. Methods of inspecting a semiconductor device for microcracks are also disclosed.

### BACKGROUND

Semiconductor devices are subjected to stresses that may create microcracks therein, particularly during assembly and packaging processes. Initially, the location and/or size of a microcrack may not affect the function of a semiconductor device, which is typically tested before the semiconductor device is singulated from a wafer and after the semiconductor device has been packaged. Semiconductor devices that pass electrical testing, but include microcracks, are at risk for future failure.

Accordingly, it would be beneficial to enable the detection of microcracks in a semiconductor device before and/or after packaging the semiconductor device.

### SUMMARY

A semiconductor device assembly of this disclosure includes a semiconductor substrate, at least one metal layer, and a polyimide layer with a visible microcrack indicator dispersed therethrough.

The semiconductor substrate may carry a plurality of circuits, which may be integrally formed in and on the semiconductor substrate. The plurality of circuits may define one or more semiconductor devices. The one or more semiconductor devices may comprise one or more memory devices, such as NAND flash or NAND memory devices.

The semiconductor substrate may also be referred to as semiconductive means. The semiconductor substrate may be a wafer that comprises a semiconductor material (e.g., a silicon wafer, etc.). Such a semiconductor substrate may carry a plurality of semiconductor devices, each of which includes a plurality of circuits. Alternatively, the semiconductor substrate may comprise a die that has been cut from a wafer that comprises a semiconductor material. Such a die may carry a single semiconductor device, which includes a plurality of circuits.

The at least one metal layer may also be referred to as “redistribution means.” The at least one metal layer may include structures that facilitate communication between the semiconductor device(s) carried by the semiconductor substrate (or, more specifically, circuits of the semiconductor device(s)) and electronic devices external to the semiconductor device(s). For example, bond pads of each semiconductor device may be defined from the at least one metal layer. In some examples, the at least one metal layer may include a plurality of layers that define bond pads, conductive traces, vias, and the like. Such a metal layer may comprise a redistribution layer (RDL) of the semiconductor device assembly.

The polyimide layer may also be referred to as a “protective layer” or as “protective means.” The polyimide layer may protect and/or insulate the metal layer. The polyimide layer is formed on the metal layer of the semiconductor device assembly. As its name implies, the polyimide layer is formed from polyimide. In addition to the conventional components of polyimide (e.g., polyamic acid, cyclohexane, a curing agent, a filler, a plasticizer, and a surfactant), the fluorescent indicator may be dispersed throughout the polyimide layer.

The fluorescent indicator may also be referred to as “fluorescent means.” The fluorescent indicator may comprise up to about 1% of the weight of the polyimide. In some examples, the fluorescent indicator may comprise a plurality of microcapsules. Each microcapsule may include a florescent core and a shell (e.g., a polymeric shell, a colloidal shell, etc.). Without limitation, each microcapsule may have a diameter of about 1 μm to about 3 μm. The fluorescent core may comprise a fluorescent dye. The shell, which may be referred to as “encapsulating means,” contains the fluorescent core. In some examples, the fluorescent core may prevent electromagnetic radiation (e.g., x-ray radiation, etc.) from exciting the fluorescent core. When the shell ruptures, or is broken, the fluorescent core may be exposed. In examples where the fluorescent core comprises a fluorescent dye, the fluorescent dye may flow into spaces adjacent to the microcapsule, such as microcracks that spread to the microcapsule to cause its shell to rupture.

A polyimide layer with a fluorescent dye may be used to facilitate detection of microcracks in semiconductor devices prior to separating individual semiconductor devices from a wafer, after separating an individual semiconductor device from the wafer but before packaging the individual semiconductor device and/or assembling the individual semiconductor device with other components of an electronic device (e.g., printed circuit boards, etc.), and/or after packaging and/or assembly processes.

Once the polyimide layer has been applied to one or more semiconductor devices, any microcracks in the polyimide layer may be detected. Microcracks may originate in the polyimide layer, or they may originate elsewhere in the semiconductor device(s), such as in the semiconductor substrate, in one or more circuits of the semiconductor device(s), or in the metal layer, and then propagate through the semiconductor device(s) and into the polyimide layer.

As a microcrack forms in and/or propagates through the polyimide layer, it may disrupt the fluorescent indicator in the polyimide layer, effectively activating the fluorescent indicator. Microcracks that extend to the top of an active layer of the semiconductor device (e.g., a metal layer, etc.) could also activate fluorescent indicators in the protective layer.

In examples where the fluorescent indicator comprises microcapsules with shells that contain a fluorescent core, the crack in the polyimide layer may extend through the shell of at least one microcapsule, exposing the fluorescent core of each microcapsule in the path of the microcrack. The exposed fluorescent core may flow into the microcrack.

A semiconductor device that includes a polyimide layer with fluorescent indicators may be inspected for the presence of microcracks in the polyimide layer. The semiconductor device may be inspected at any of a variety of points before, during, and after its packaging. For example, the semiconductor device may be inspected before the semiconductor substrate (e.g., wafer, etc.) on which the semiconductor device was fabricated is diced, or cut, to separate individual semiconductor devices from each other; i.e., before die singulation. As another example, the semiconductor device may be inspected after it has been separated, or diced, from other semiconductor devices, or after die singulation. As yet another example, the semiconductor device may be inspected before and after packaging processes (e.g., assembly, bonding, underfill, encapsulation, etc.). In some examples, a semiconductor device may be inspected for microcracks at a plurality of different points after applying the polyimide layer and before the manufacturer ships it to a customer.

The inspection may include imaging of the semiconductor device. Imaging may be facilitated by radiation (e.g., x-ray radiation, etc.). When irradiated, any fluorescent indicator in or along a microcrack may be excited in a manner that renders the microcrack or a portion thereof visually distinct from other locations of the semiconductor device. For example, a fluorescent indicator that has been released by disruption of a shell of a microcapsule by a microcrack and that has flowed into the microcrack may appear in a micrograph, or a magnified image or, more simply, an image, of the semiconductor device as a dark feature that is visibly distinct from laterally adjacent features of the semiconductor device. Thus, the fluorescent indicators may render any microcracks in the polyimide layer visible to an individual viewing the image of the semiconductor device.

Other aspects of the disclosed subject matter, as well as features and advantages of various aspects of the disclosed subject matter, should be apparent to those of ordinary skill in the art through consideration the ensuing description, the accompanying drawings, and the appended claims.

### BRIEF DESCRIPTION OF THE DRAWINGS

Non-limiting and non-exhaustive examples are described with reference to the following Figures.

FIG. 1 is a cross-sectional representation of a semiconductor device, including a semiconductor substrate, an active layer that includes circuits carried by the semiconductor substrate and a metal layer with structures that facilitate communication between the circuits and external electronic devices, and a protective layer over the active layer;

FIG. 2 is an x-ray micrograph of a semiconductor device of the type shown in FIG. 1, in which any microcracks are not visible;

FIG. 3 depicts a process for forming a protective layer over a plurality of semiconductor devices;

FIG. 4 is a cross-sectional representation of an example of a semiconductor device with a semiconductor substrate, an active layer, and a protective layer over the active layer, with the protective layer including fluorescent indicators;

FIG. 5 is an orthogonal representation of the example of the semiconductor device shown in FIG. 4;

FIG. 6 illustrates an example of a fluorescent indicator that may be included in a protective layer for a semiconductor device;

FIG. 7 is an orthogonal representation of the example of the semiconductor device shown in FIGS. 4 and 5, with a microcrack extending through the protective layer and fluorescent indicator within the microcrack; and

FIG. 8 is an example of an x-ray micrograph of a semiconductor device in which microcracks are visible.

### DETAILED DESCRIPTION

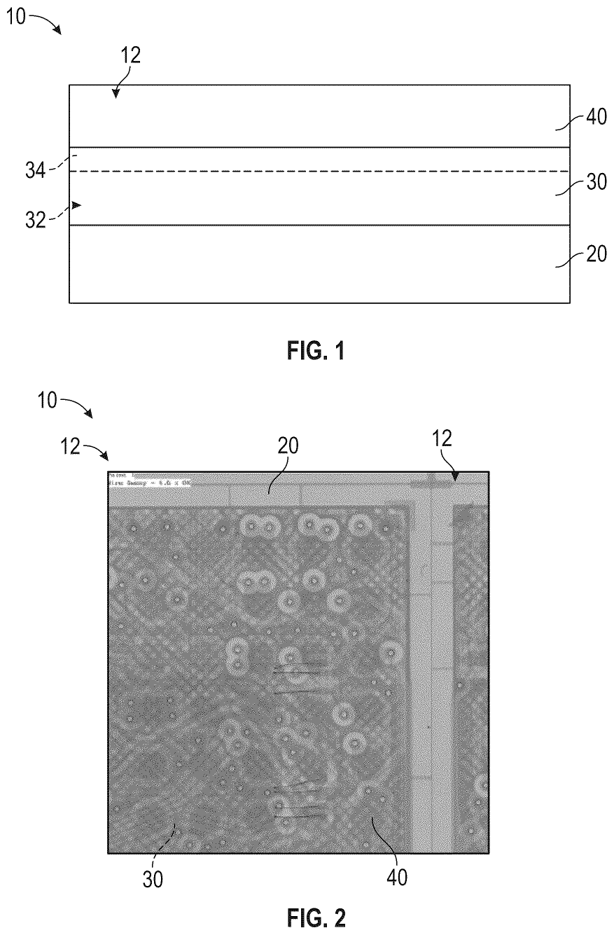

FIG. 1 provides a cross-sectional representation of a semiconductor device 10. The semiconductor device 10 includes a semiconductor substrate 20, and active layer 30 on the semiconductor substrate 20, and a protective layer 40 on the active layer 30. Without limitation, the semiconductor device 10 may comprise an individual integrated circuit 12 that has been singulated from other integrated circuits 12 or, as illustrated by FIG. 2, the semiconductor device 10 may comprise a plurality of discrete integrated circuits 12 that have not yet been singulated, or separated or diced, from each other. Each integrated circuit 112 may comprise a memory device, such as a NAND flash device.

The semiconductor substrate 20 may comprise any suitable semiconductor substrate. Without limitation, the semiconductor substrate 20 may comprise a semiconductor material—typically silicon, although other semiconductor materials (e.g., gallium arsenide, indium phosphide, etc.) may also be used. The semiconductor substrate 20 may consist of the semiconductor material or it may comprise a layer of the semiconductor material on a substrate formed from an electrical insulator, such as glass (as in silicon-on-glass (SOG)), sapphire (as in silicon-on-sapphire (SOS)), or the like. In examples where the semiconductor substrate 20 comprises a wafer, the wafer may carry a plurality of discrete integrated circuits 12 that have yet to be singulated from each other. Alternatively, the semiconductor substrate 20 may comprise a die, or an integrated circuit chip, that has been cut, or diced, from a wafer and carries a single integrated circuit 12.

The active layer 30 may comprise the circuits 32 that have been fabricated with and on the semiconductor substrate 20 and that define one or more integrated circuits 12 (FIG. 2) on the semiconductor substrate 20. In addition, the active layer 30 may include a metal layer 34 over the circuits 32. The metal layer 34 may include structures that facilitate communication between the circuits 32 and electronic devices (not shown) that are external to each semiconductor device 10. For example, bond pads of each individual semiconductor device 10 may be defined from the metal layer 34. In some examples, the metal layer 34 may include a plurality of sublayers that define bond pads, conductive traces, vias, and the like. Such a metal layer 34 may define a redistribution layer (RDL) of each individual semiconductor device 10.

The protective layer 40 may comprise a patterned layer of a dielectric material that electrically insulates and protects the layers that lie beneath it, including the metal layer 34 and the circuits 32 of the active layer 30. The protective layer 40 may be formed from polyimide that has been patterned to expose any bond pads (not shown) of the metal layer 34 and to expose the spaces between adjacent integrated circuits 12.

As a microcrack forms in any of the layers of a semiconductor device 10, it may propagate across that layer or into adjacent layers. For example, a microcrack that starts in the semiconductor substrate 20 may spread into the active layer 30; a microcrack in the active layer 30 may spread to the protective layer 40; a microcrack that starts in the protective layer 40 may propagate into the active layer 30. Some microcracks in a semiconductor device 10 may affect the circuity of the semiconductor device 10, affecting its ability to function properly. Other microcracks may not affect the circuitry of the semiconductor device 10. Over time, however, a variety of factors may cause such microcracks to propagate into the circuitry of the semiconductor device, leading to a cascade of problems that can ultimately result in failure of the semiconductor device 10. These factors include thermal cycling of the semiconductor device 10 during repeated use, as well as forces acting on the semiconductor device 10 (e.g., vibration, shock from impacts, etc.).

Microcracks are typically not visible while imaging a semiconductor device 10 (e.g., with an x-ray imager, etc.). Any damage they may cause is typically detected by electrically testing the circuitry of the semiconductor device 10. While electrical testing reveals microcracks and other issues that affect the circuitry of a semiconductor device 10, electrical testing does not reveal microcracks that have not yet propagated into the circuitry of the semiconductor device 10.

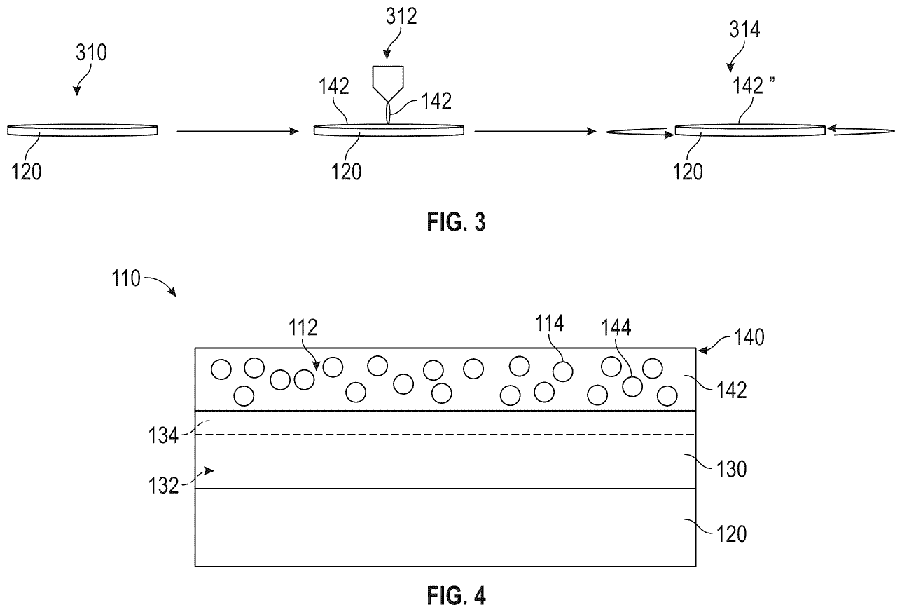

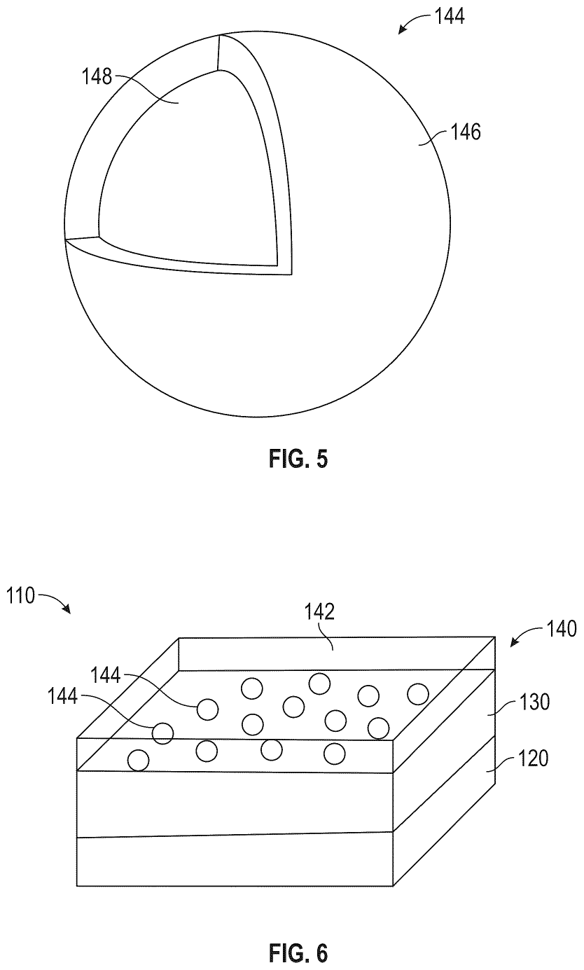

FIG. 3 illustrates a process for facilitating the visual detection of microcracks in semiconductor devices. At reference 310, a semiconductor substrate 120, such as a wafer, is provided. The semiconductor substrate 120 carries an active layer 130 (FIGS. 4 and 5), including circuits 132 (FIG. 4) that define a plurality of integrated circuits 112 (FIGS. 4 and 8) and a metal layer 134 (FIG. 4) that defines features (e.g., bond pads, conductive traces, vias, etc.) associated with each integrated circuit 112.

A volume of a dielectric material 142 with fluorescent indicators 144 (FIG. 4) dispersed therethrough is applied to the active layer 130 at reference 312 of FIG. 3. The dielectric material 142 may be dispensed in a liquid form. For example, the photopolymer 142 may comprise an un-crosslinked photoimagable polymer, such as polyimide.

As shown at reference 314, the photopolymer 142 may be spun onto the active layer 130 (FIG. 4) on the semiconductor substrate 120 in a manner known in the art. Spinning the photopolymer 142 onto the active layer 130 may spread the photopolymer actively across the active layer 130, providing a photopolymer layer 142′ of a desired thickness. The photopolymer layer 142′ may then be patterned in a manner known in the art to expose desired portions of the metal layer 134 (FIG. 4) (e.g., bond pads, etc.), as well as the spaces between adjacent integrated circuits 112 (FIGS. 4 and 8) to facilitate their subsequent singulation from each other. Patterning of the photopolymer layer 142′ defines a protective layer 140 atop each integrated circuit 112.

FIG. 4 provides a cross-sectional representation of a semiconductor device 110 with a protective layer 140 on its active layer 130. More specifically, the semiconductor device 110 includes a semiconductor substrate 120, an active layer 130 on the semiconductor substrate 120, and a protective layer 140 over the active layer 130. The protective layer 140 includes fluorescent indicators 144. The semiconductor device 110 may comprise an individual integrated circuit 112 that has been singulated from other integrated circuits 112 or, as illustrated by FIG. 8, the semiconductor device 110 may comprise a plurality of discrete integrated circuits 112 that have not yet been singulated from each other. Each integrated circuit 112 may comprise a memory device, such as a NAND flash device.

The semiconductor substrate 120 may comprise any suitable semiconductor substrate. The semiconductor substrate 120 may comprise a semiconductor material, such as silicon or any other suitable semiconductor material (e.g., gallium arsenide, indium phosphide, etc.). The semiconductor substrate 120 may consist of the semiconductor material or it may comprise a layer of the semiconductor material on a substrate formed from an electrical insulator, such as glass (as in SOG), sapphire (as in SOS), or the like. In examples where the semiconductor substrate 120 comprises a wafer, the wafer may carry a plurality of discrete integrated circuits 112 that not yet been singulated from each other. Alternatively, the semiconductor substrate 120 may comprise a die, or an integrated circuit chip, that has been cut, or diced, from a wafer and carries a single integrated circuit 112.

The active layer 130 may comprise the circuits 132 that have been fabricated with and on the semiconductor substrate 120 and that define one or more integrated circuits 112 on the semiconductor substrate 120. In addition, the active layer 130 may include a metal layer 134 over the circuits 132. The metal layer 134 may include structures that facilitate communication between the circuits 132 and electronic devices (not shown) that are external to each semiconductor device 110. For example, bond pads of each individual semiconductor device 110 may be defined from the metal layer 134. In some examples, the metal layer 134 may include a plurality of sublayers that define bond pads, conductive traces, vias, and the like. Such a metal layer 134 may define a redistribution layer (RDL) of each individual semiconductor device 110.

The protective layer 140 may comprise a patterned layer of a dielectric material 142 (e.g., polyimide, etc.). The dielectric material 142 may electrically insulate and protect the layers that lie beneath it, including the metal layer 134 and the circuits 132 of the active layer 130. The dielectric material 142 includes fluorescent indicators 144 dispersed therethrough. The fluorescent indicators 144 may comprise up to about 1% of a weight of the dielectric material 142.

More specifically, the dielectric material 142 may include polyamic acid, cyclohexane, a surfactant, a curing agent, one or more fillers, a plasticizer, and the fluorescent indicators 144. The polyamic acid is a precursor to polyimide. The cyclohexane is a solvent for the polyamic acids and other components of the dielectric material. The surfactant improves wetting of the dielectric material 142 and its components, helping the dielectric material 142 uniformly coat the active layer 130. The curing agent promotes the imidization reaction between molecules of the polyamic acid. Fillers impart the dielectric material 142 with mechanical strength and thermal conductivity. The plasticizer may enhance the flexibility and processability of the polyimide.

An example of a fluorescent indicator 144 is depicted by FIG. 5. The fluorescent indicator 144 may comprise a microcapsule. Such a fluorescent indicator 144 may include a shell 146 that contains a fluorescent core 148. Such a fluorescent indicator 144 may have a diameter of about 1 μm to about 3 μm.

The fluorescent core 148 may comprise a material that, when exposed to a wavelength or bandwidth of radiation (e.g., x-ray radiation, etc.), will fluoresce, emitting radiation that will be visible on an image, such as a radiograph. The fluorescent core 148 may comprise a liquid

A material of the shell 146 may limit the extent to which suitable radiation (e.g., x-ray radiation, etc.) will excite the fluorescent core 148 of the fluorescent indicator 144. In some examples, the material of the shell 146 may prevent such radiation from exciting the fluorescent core 148. The material of the shell 146 may be compatible with the dielectric material 142 (e.g., the polyimide, etc.). The shell 146 may comprise a polymer, although other suitable materials may also be used. The material of the shell 146 may interact with (e.g., adhere to, bond to, etc.) the dielectric material 142 in such a way that a microcrack that intersects to the shell 146 while the microcrack propagates will also propagate through the shell 146, rupturing the shell 146.

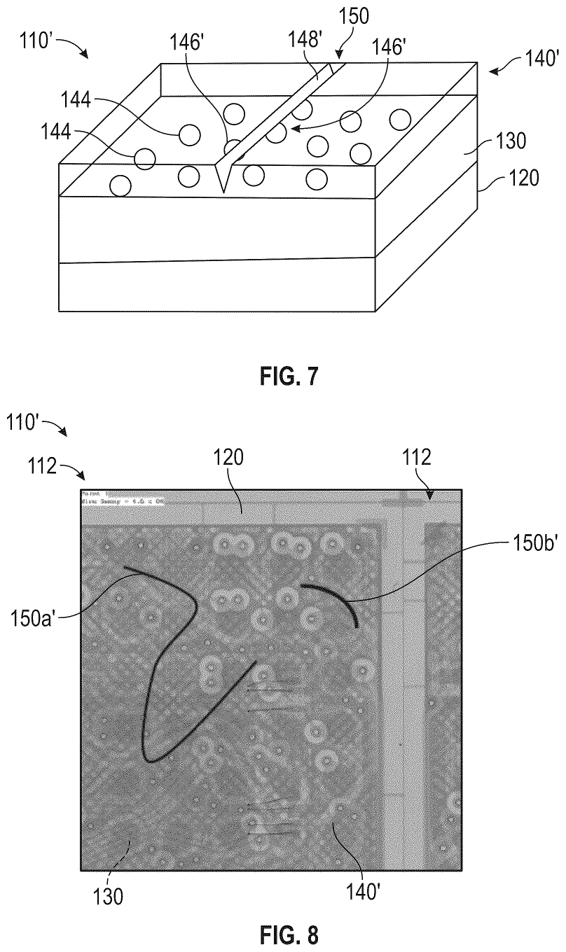

As a microcrack ruptures the shell 146, the fluorescent core 148 is exposed. In examples where the fluorescent core 148 is a liquid, it may flow out the ruptured shell 146 and into an adjacent microcrack 150 (FIG. 7). As the exposed fluorescent core 148 is subjected to an appropriate wavelength or bandwidth of radiation (e.g., x-ray radiation, etc.), the fluorescent core 148 may fluoresce, producing a visible artifact on an image, or radiograph, of the protective layer 140.

FIG. 6 depicts a semiconductor device 110 prior to the formation or propagation of any microcracks. Again, the semiconductor device 110 includes a semiconductor substrate 120, an active layer 130, and a protective layer 140. The protective layer 140 is formed from a dielectric material 142 that includes fluorescent indicators 144 dispersed therethrough. An image obtained under appropriate radiation may appear the same as the image provided in FIG. 2, in which no microcracks are visible (in this case, because there are no microcracks in the protective layer 140).

In FIG. 7, a microcrack 150 has formed in the semiconductor device 110′. More specifically, the microcrack 150 has formed in or propagated through the protective layer 140 of the semiconductor device 110′. As the microcrack 150 propagated through the protective layer 140′, it intersected some of the fluorescent indicators 144, rupturing their shells 146′ and exposing their fluorescent cores 148′. In examples where the fluorescent cores 148′ are liquid, they may flow along the microcrack 150, including portions of the microcrack that extend into the active layer 130 of the semiconductor device 110′. Microcracks 150 in the active layer 130 of the semiconductor device 100′ that extend to the top of the active layer 130 could also activate fluorescent indicators 144 in portions of the protective layer 140 adjacent to such microcracks 150.

FIG. 8 provides an example of an image of the semiconductor device 110′ obtained while exposing the semiconductor device 110′ to appropriate radiation (e.g., x-ray radiation, etc.). As FIG. 8 shows, the exposed fluorescent cores 148′ illuminate microcracks 150a′ and 150b′ in the protective layer 140′ and/or portions of the active layer 130 adjacent to the protective layer 140′, highlighting damage to the semiconductor device 110′ that may not be apparent when the semiconductor device 110′ is exposed to electrical testing that conventionally precedes assembly and packaging processes.

With continued reference to FIGS. 6-8, a method of determining whether any microcracks have formed in a semiconductor device 110, 110′ includes inspecting the semiconductor device 110, 110′. The semiconductor device 110, 110′ may be inspected at any of a variety of points in time before, during, and after packaging of the semiconductor device 110, 110′. For example, the semiconductor device 110, 110′ may be inspected before the semiconductor substrate 120 (e.g., wafer, etc.) on which the semiconductor device 110, 110′ was fabricated is diced, or cut, to separate individual integrated circuits 112 (FIG. 4) from each other; i.e., before die singulation. As another example, the semiconductor device 110, 110′ may be inspected after it has been separated from other semiconductor devices 110, 110′, or after die singulation. As yet another example, the semiconductor device 110, 110′ may be inspected before and after packaging processes (e.g., assembly, bonding, underfill, encapsulation, etc.). In some examples, a semiconductor device 110, 110′ may be inspected for microcracks 150 at a plurality of different points in time after applying the protective layer 140, 140′ and before the manufacturer ships the semiconductor device 110, 110′ or a package including the semiconductor device 110, 110′ to a customer.

Inspection of the semiconductor device 110, 110′ may include subjecting the semiconductor device 110, 110′ to an appropriate wavelength or bandwidth of radiation (e.g., x-ray radiation, etc.) and, while irradiating the semiconductor device 110, 110′, obtaining an image, such as a micrograph, of the semiconductor device 110, 110′. When irradiated, any fluorescent indicator 144 in or along a microcrack 150 may be excited in a manner that renders the microcrack 150 or a portion thereof visually distinct from other locations of the semiconductor device 110′.

For example, as illustrated by FIG. 7, in examples where the fluorescent indicator 144 comprises microcapsules, a fluorescent core 148′ that has been released by disruption of a shell 146′ by a microcrack 150 and that has flowed into the microcrack 150 may appear in a micrograph, or a magnified image or, more simply, an image, of the semiconductor device 110′, as depicted by FIG. 8, as a dark feature that is visibly distinct from laterally adjacent features of the semiconductor device 110′. Thus, the fluorescent indicators 144 may render any microcracks 150 in the polyimide layer visible to an individual viewing the image of the semiconductor device.

Alternatively, if no microcrack forms in or adjacent to the protective layer 140 of a semiconductor device 110, such as that depicted by FIG. 6, the fluorescent indicator 144 of the protective layer 140 of the semiconductor device 110 will not be affected. Thus, no microcracks will be visible in an image of the semiconductor device 110; the image of such a semiconductor device 110 will appear similar to the micrograph shown in FIG. 2.

Radiographic imaging of semiconductor devices 110, 110′ may supplement conventional electrical testing of the semiconductor devices 110, 110′. A semiconductor device 110′ that has failed electrical testing may be radiographically inspected to determine whether one or more microcracks were responsible for the failed electrical test(s). Similarly, a semiconductor device 110, 110′ that has malfunctioned or failed during use may be radiographically inspected to determine whether microcracks lead to the malfunction or failure of the semiconductor device 110, 110′. A semiconductor device 110, 110′ that has passed electrical testing may be radiographically inspected for microcracks to determine whether future microcrack-induced malfunction or failure is possible or likely.

Based on the above, examples of the present disclosure describe a semiconductor device assembly, comprising: a semiconductor substrate carrying a plurality of circuits; at least one metal layer over the semiconductor substrate; and a polyimide layer on the at least one metal layer, the polyimide layer including a fluorescent indicator dispersed therethrough, bond pads of the at least one metal layer being exposed through the polyimide layer. In an example, the fluorescent indicator comprises up to about 1% of a weight of the polyimide layer. In an example, the fluorescent indicator includes microcapsules with a fluorescent core and a shell. In an example, each fluorescent indicator includes a microcapsule with a fluorescent core and a shell. In an example, each microcapsule of the plurality of microcapsules has a diameter of about 1 μm to about 3 μm. In an example, the semiconductor substrate comprises a wafer comprising a semiconductor material carrying a plurality of semiconductor devices. In an example, the metal layer comprises at least one redistribution layer. In an example, the semiconductor substrate comprises a die that has been cut from a wafer comprising a semiconductor material. In an example, the semiconductor device assembly also includes a NAND memory device.

Other examples describe a semiconductor device assembly, comprising: semiconductive means for carrying a plurality of circuits; redistribution means for establishing communication between the plurality of circuits and electronic devices external to the semiconductor device; and protective means for insulating the redistribution means, the protective means comprising fluorescent means for identifying microcracks in the protective means, the fluorescent means dispersed throughout the protective means, bonding means for establishing communication with an electronic device external to the semiconductor device exposed through the protective means. In an example, the fluorescent means comprises up to about 1% of a weight of the protective means. In an example, the fluorescent means comprises encapsulating means for containing a fluorescent material. In an example, the fluorescent means has a diameter of about 1 μm to about 3 μm. In an example, the semiconductive means comprises a wafer comprising a semiconductor material. In an example, the semiconductive means comprises a die cut from a wafer comprising a semiconductor material.

Still other examples describe a method for detecting a microcrack in a semiconductor device, comprising: forming a polyimide with a fluorescent indicator dispersed therethrough; applying the polyimide over a metal layers of a plurality of semiconductor devices on a wafer to form a polyimide layer with the fluorescent indicator dispersed therethrough; x-ray-imaging at least one semiconductor device of the plurality of semiconductor devices to provide an image of the at least one semiconductor device, any microcrack in the at least one semiconductor device appearing as a dark line in the image; and visualizing the image to identify the microcrack in the at least one semiconductor device. In an example, forming the polyimide comprises forming the polyimide with the fluorescent indicators comprising up to about 1% of a weight of the polyimide. In an example, forming the polyimide comprises forming the polyimide with the fluorescent indicators comprising encapsulated fluorescent indicators. In an example, the microcrack extends through at least one microcapsule of the encapsulated fluorescent indicators, exposing a fluorescent material of the at least one microcapsule. In an example, the fluorescent material flows from the at least one microcapsule into the microcrack.

Although this disclosure provides many specifics, these should not be construed as limiting the scope of any of the claims that follow, but merely as providing illustrations of some examples of elements and features of the disclosed subject matter. Other examples of the disclosed subject matter, and of their elements and features, may be devised which do not depart from the spirit or scope of any of the claims. Features from different examples may be employed in combination. Accordingly, the scope of each claim is limited only by its plain language and the legal equivalents thereto.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed:

1. A semiconductor device assembly, comprising:
a semiconductor substrate carrying a plurality of circuits;
at least one metal layer over the semiconductor substrate; and
a polyimide layer on the at least one metal layer, the polyimide layer including a fluorescent indicator dispersed therethrough, bond pads of the at least one metal layer being exposed through the polyimide layer.

2. The semiconductor device assembly of claim 1, wherein the fluorescent indicator comprises up to about 1% of a weight of the polyimide layer.

3. The semiconductor device assembly of claim 1, wherein the fluorescent indicator includes microcapsules with a fluorescent core and a shell.

4. The semiconductor device assembly of claim 3, wherein each fluorescent indicator includes a microcapsule with a fluorescent core and a shell.

5. The semiconductor device assembly of claim 3, wherein each microcapsule of the plurality of microcapsules has a diameter of about 1 μm to about 3 μm.

6. The semiconductor device assembly of claim 1, wherein the semiconductor substrate comprises a wafer comprising a semiconductor material carrying a plurality of semiconductor devices.

7. The semiconductor device assembly of claim 1, wherein the metal layer comprises at least one redistribution layer.

8. The semiconductor device assembly of claim 1, wherein the semiconductor substrate comprises a die that has been cut from a wafer comprising a semiconductor material.

9. The semiconductor device assembly of claim 1, comprising a NAND memory device.

10. A semiconductor device assembly, comprising:
semiconductive means for carrying a plurality of circuits;
redistribution means for establishing communication between the plurality of circuits and electronic devices external to the semiconductor device; and
protective means for insulating the redistribution means, the protective means comprising fluorescent means for identifying microcracks in the protective means, the fluorescent means dispersed throughout the protective means, bonding means for establishing communication with an electronic device external to the semiconductor device exposed through the protective means.

11. The semiconductor device assembly of claim 10, wherein the fluorescent means comprises up to about 1% of a weight of the protective means.

12. The semiconductor device assembly of claim 11, wherein the fluorescent means comprises encapsulating means for containing a fluorescent material.

13. The semiconductor device assembly of claim 12, wherein the fluorescent means has a diameter of about 1 μm to about 3 μm.

14. The semiconductor device assembly of claim 10, wherein the semiconductive means comprises a wafer comprising a semiconductor material.

15. The semiconductor device assembly of claim 10, wherein the semiconductive means comprises a die cut from a wafer comprising a semiconductor material.

16. A method for detecting a microcrack in a semiconductor device, comprising:
forming a polyimide with a fluorescent indicator dispersed therethrough;
applying the polyimide over a metal layers of a plurality of semiconductor devices on a wafer to form a polyimide layer with the fluorescent indicator dispersed therethrough;
x-ray-imaging at least one semiconductor device of the plurality of semiconductor devices to provide an image of the at least one semiconductor device, any microcrack in the at least one semiconductor device appearing as a dark line in the image; and
visualizing the image to identify the microcrack in the at least one semiconductor device.

17. The method of claim 16, wherein forming the polyimide comprises forming the polyimide with the fluorescent indicators comprising up to about 1% of a weight of the polyimide.

18. The method of claim 16, wherein forming the polyimide comprises forming the polyimide with the fluorescent indicators comprising encapsulated fluorescent indicators.

19. The method of claim 18, wherein the microcrack extends through at least one microcapsule of the encapsulated fluorescent indicators, exposing a fluorescent material of the at least one microcapsule.

20. The method of claim 19, wherein the fluorescent material flows from the at least one microcapsule into the microcrack.
